(19) United States
(12) Patent Application Publication
(10) Pub. No.: US 2024/0009875 A1
(43) Pub. Date: Jan. 11, 2024

(54) RAZOR BLADE AND RAZOR CARTRIDGE INCLUDING THE SAME

(71) Applicant: DORCO CO., LTD., Seoul (KR)

(72) Inventor: Min Joo PARK, Seoul (KR)

(21) Appl. No.: 18/349,499

(22) Filed: Jul. 10, 2023

(30) Foreign Application Priority Data
Jul. 11, 2022 (KR) 10-2022-0084868

(51) Int. Cl. B26B 21/60; B26B 21/56

(52) U.S. Cl. CPC B26B 21/60; B26B 21/565; B26B 21/443

(57) ABSTRACT

A razor blade and a razor cartridge including the same are proposed. The razor blade may include a substrate including a substrate tip, a first surface extending from the substrate tip to a first side, and a second surface extending from the substrate tip to a second side opposing the first side. The razor blade may also include a metal coating layer formed on the first surface, the second surface, and the substrate tip, in which the metal coating layer includes a plurality of columnar structures formed toward an outside of the substrate.

### CROSS-REFERENCE TO RELATED APPLICATIONS

This application claims the benefit of Korean Patent Application No. 10-2022-0084868, filed on Jul. 11, 2022 and Korean Patent Application No. 10-2023-0089337, filed on Jul. 10, 2023, the contents of which are all hereby incorporated by reference herein in their entirety.

### BACKGROUND

### Technical Field

The present disclosure relates to a razor blade and a razor cartridge including the same, and more particularly, to a razor blade used in a disposable razor or a cartridge replaceable razor and a razor cartridge including the same.

### Description of the Related Technology

A razor is used to cut and remove hair such as beard and mustache or fine hair on the face or body. The configuration of the razor is largely composed of a handle gripped by the user and a razor cartridge including at least one blade that cuts body hairs according to the movement of the handle. The razor cartridge is used for a disposable razor in which the cartridge cannot be replaced or a cartridge replaceable razor in which the cartridge is detachable from the handle.

### SUMMARY

One aspect is a razor blade and a razor cartridge including the same that can improve blade durability with a reduced blade cutting force by controlling a structure shape of a metal coating layer into a columnar shape when forming a metal coating layer on a substrate.

Another aspect is a razor blade including: a substrate including a substrate tip, a first surface extending from the substrate tip to one side, and a second surface extending from the substrate tip to the other side; and a metal coating layer formed on the first surface, the second surface, and the substrate tip, in which the metal coating layer includes a plurality of columnar structures formed toward an outside of the substrate.

Another aspect is a razor cartridge including: at least one blade including an edge portion and a cutting edge formed at a tip of the edge portion; and a blade housing configured to accommodate the blade in a longitudinal direction such that at least a portion of the cutting edge is exposed upward, in which the razor blade includes a substrate including a substrate tip, a first surface extending from the substrate tip to one side, and a second surface extending from the substrate tip to the other side, and a metal coating layer formed on the first surface, the second surface, and the substrate tip, and the metal coating layer includes a plurality of columnar structures formed toward an outside of the substrate.

Details of other embodiments are included in the detailed description and drawings.

By forming a plurality of columnar structures when forming a metal coating layer on a substrate, the cutting force of the blade during shaving can be reduced and durability of the blade can be improved.

### BRIEF DESCRIPTION OF THE DRAWINGS

FIG. 1 is a schematic side view of a razor.

FIG. 2 is a plan view of a razor cartridge according to an embodiment of the present disclosure illustrated in FIG. 1.

FIG. 3 is a cross-sectional view taken along line III-III illustrated in FIG. 2.

FIG. 4 is a configuration diagram of a blade illustrated in FIG. 3.

FIG. 5 is an enlarged cross-sectional view of an area A illustrated in FIG. 4.

FIG. 6 is a configuration diagram illustrating a substrate and a metal coating layer in the cutting edge area of the blade illustrated in FIG. 5.

FIG. 7 is an enlarged cross-sectional view of an area B illustrated in FIG. 6.

FIG. 8 is a schematic process diagram of forming a plurality of columnar structures illustrated in FIGS. 5 to 7 by a sputtering process.

FIGS. 9A and 9B are schematic configuration diagrams of a shape of a columnar structure of a razor blade according to an embodiment of the present disclosure.

FIG. 10 is a first shape view of a substrate and a metal coating layer in a cutting edge area of the blade illustrated in FIG. 6.

FIG. 11 is a cross-sectional view illustrating a cutting edge area facing a skin surface.

FIGS. 12A to 12C are cross-sectional views illustrating a relative angle between the skin surface and the cutting edge area illustrated in FIG. 11.

FIG. 13 is a graph of a durability test of a conventional blade and a blade of a razor cartridge according to an embodiment of the present disclosure.

### DETAILED DESCRIPTION

A blade generally comprises a substrate made of a metal material such as stainless steel, and is formed to have a cutting edge including a substrate tip. The blade may include a metal coating layer made of carbide, diamond-like carbon (DLC), nitride, or the like on the substrate, and thus, the blade has improved durability and cutting force compared to a blade without a metal coating layer.

The metal coating layer may be formed by a method such as chemical vapor deposition (CVD) or physical vapor deposition (PVD).

The blade may include a polymer material, specifically, a resin coating layer such as polytetrafluoroethylene (PTFE), on the metal coating layer, and thus, the blade has improved lubrication performance and friction reducing effects compared to a blade without a resin coating layer.

Meanwhile, when forming a metal coating layer on a substrate, since a cutting force and durability of the blade are determined according to a thin film thickness and a thin film shape according to the location of the substrate, such as a substrate tip and both side surfaces of the substrate, a technology that can optimize the cutting force and durability of the blade are required.

Hereinafter, a razor blade according to an embodiment of the present disclosure and a razor cartridge including the same will be described in detail with reference to the accompanying drawings.

Prior to the description, the razor blade and the razor cartridge including the same according to the embodiment of the present disclosure may be integrally formed with a handle of a disposable razor, and may be selectively combined with the handle of a cartridge replaceable razor.

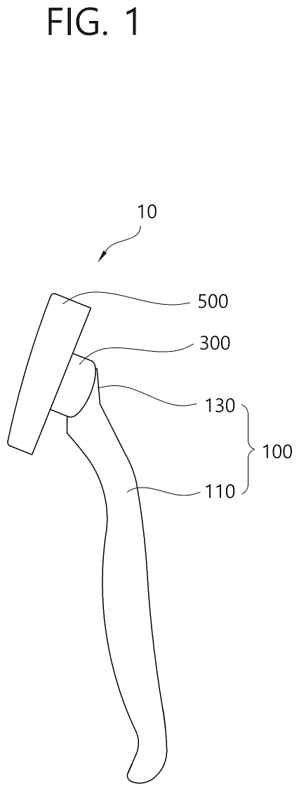

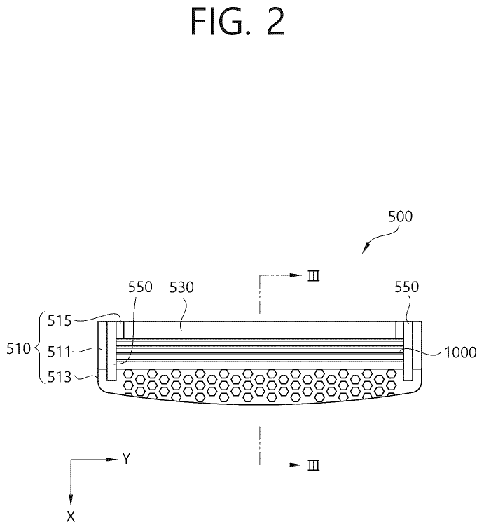

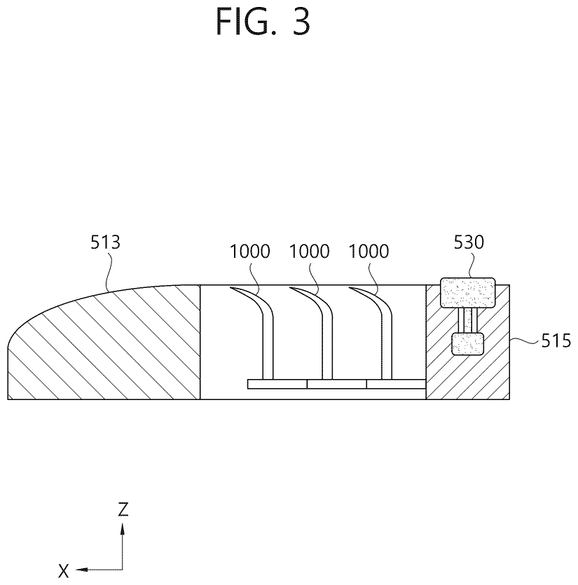

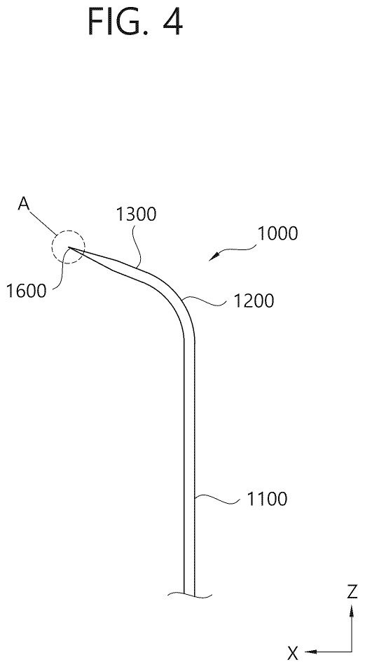

FIG. 1 is a schematic side view of a razor, FIG. 2 is a plan view of a razor cartridge according to an embodiment of the present disclosure illustrated in FIG. 1, FIG. 3 is a cross-sectional view taken along line III-III illustrated in FIG. 2, and FIG. 4 is a configuration diagram of a blade illustrated in FIG. 3.

As illustrated in FIGS. 1 to 4, a razor 10 includes a handle 100, a handle coupler 300, and a razor cartridge 500 according to an embodiment of the present disclosure.

The handle 100 is gripped by a user. The handle 100 includes a handle body 110 and a handle header 130.

The handle body 110 is a part gripped by the user of the razor 10. The handle header 130 is provided on one end of the handle body 110 and is detachably coupled to the razor cartridge 500. Moreover, the handle body 110 rotatably supports the selectively coupled razor cartridge 500. Here, the handle body 110 is manufactured integrally with the razor cartridge 500 in the case of a disposable razor.

The handle header 130 is coupled to the handle coupler 300 formed at a lower portion of the razor cartridge 500. The handle header 130 is coupled to the handle coupler 300 to support the razor cartridge 500 to rotate within a predetermined angle range with respect to a fixed axis or an axis that moves within a predetermined range.

In addition, the handle header 130 is selectively coupled to the handle coupler 300 in the cartridge replaceable razor. In this case, the handle 100 may be provided with an operation means (not illustrated) that can operate the handle header 130. The user can release the coupling between the handle header 130 and the handle coupler 300 by operating the operation means.

The razor cartridge 500 according to the embodiment of the present disclosure includes a blade housing 510, a lubrication band 530, a clip 550, and a razor blade (1000: hereinafter referred to as a “blade”).

The blade housing 510 includes a frame 511, a guard 513, and a cap 515. Here, the guard 513 is disposed in the front (positive X-axis direction) of the frame 511 with the frame 511 as the center, and the cap 515 is disposed in the rear (negative X-axis direction) of the frame 511 with the frame 511 as the center.

The central portion of the frame 511 is formed to open toward the top. The frame 511 accommodates at least one blade 1000 in the longitudinal direction (Y-axis direction). When the plurality of blades 1000 are disposed in the frame 511, each blade 1000 may be arranged in a row in a transverse direction (X-axis direction) with respect to the other blades 1000.

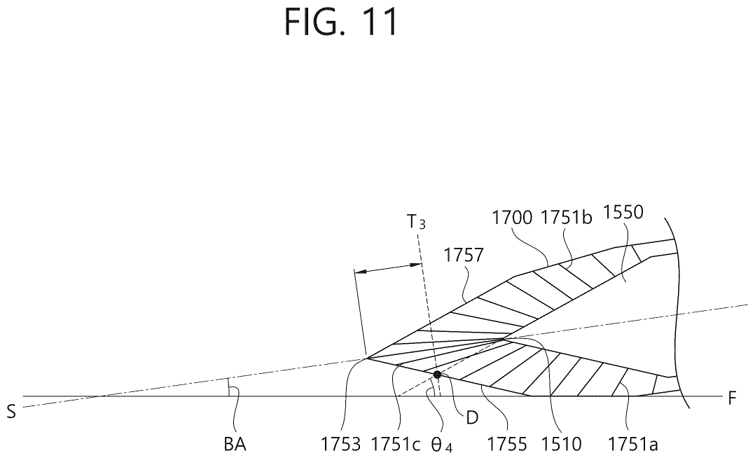

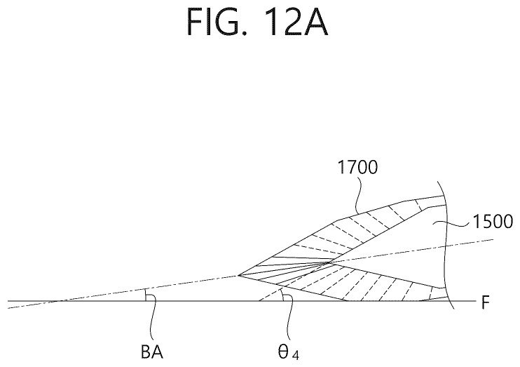

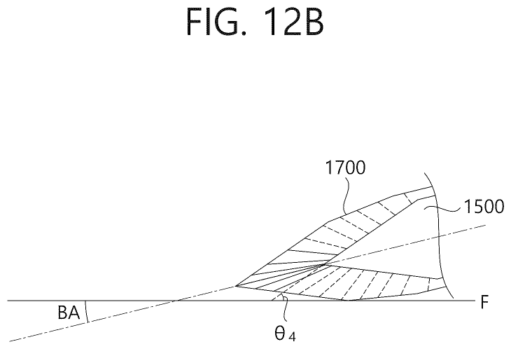

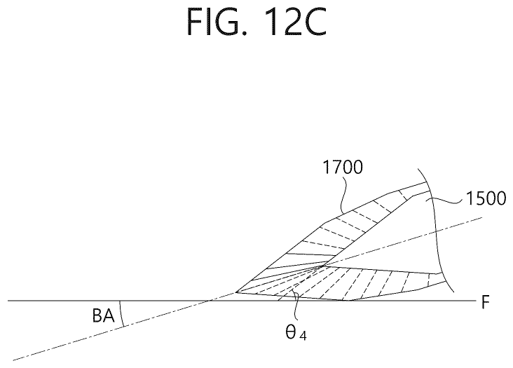

The guard 513 comes into close contact with the skin surface (F: see FIGS. 11 and 12) of the user during shaving to improve the shaving effect by the blade 1000 by pulling the skin surface F. A protruding or recessed pattern may be formed on the upper surface of the guard 513 to pull the skin surface F of the user more effectively. The upper surface of the guard 513 may be formed of a quality such as rubber or silicone, but the present invention is not limited thereto. That is, depending on the purpose, the guard 513 may contain a lubricating material to apply a lubricating material to the skin before shaving, or may be manufactured to have a predetermined roughness to have a function of removing dead skin cells from the skin.

The lubrication band 530 exposed to the top of the razor cartridge 500 may be disposed in the cap 515. The lubricating band 530 includes a lubricating material, and allows the lubricating material to be applied to a skin surface F where the blade 1000 passes during shaving. The lubricating material may include components for protecting the skin surface F after shaving.

The clip 550 surrounds both sides of the frame 511 and is coupled to the blade housing 510. The clip 550 prevents the blade 1000 from being separated from the blade housing 510.

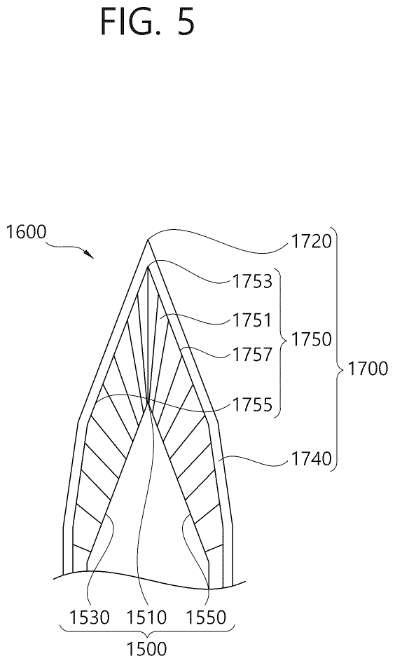

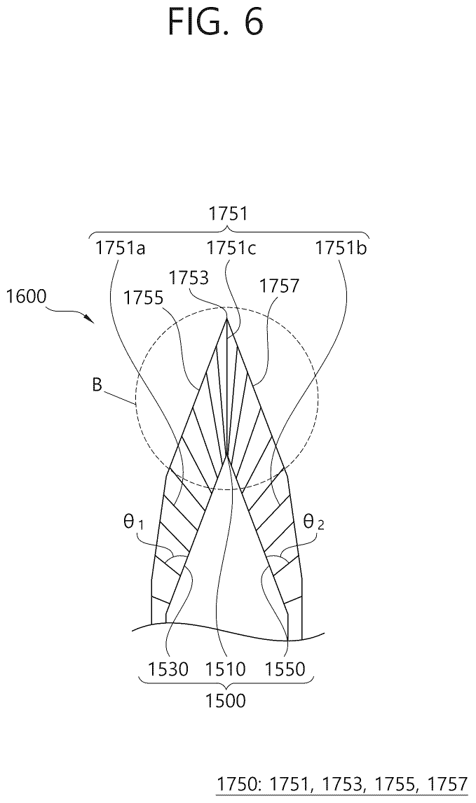

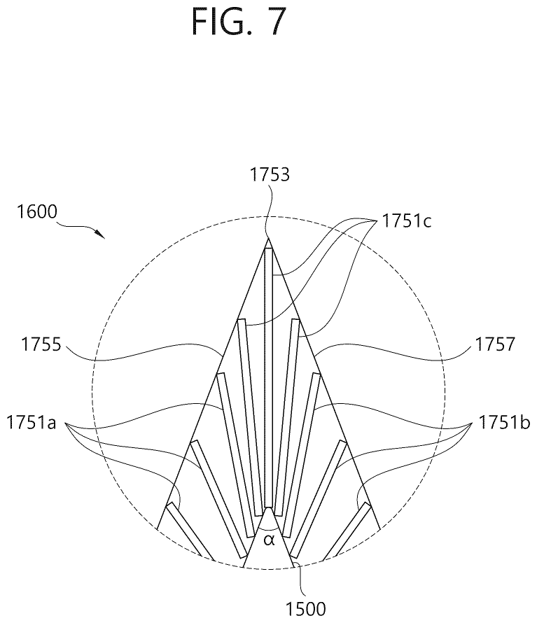

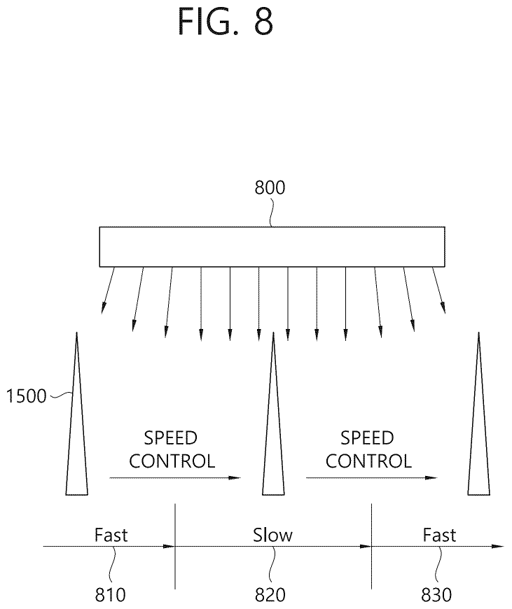

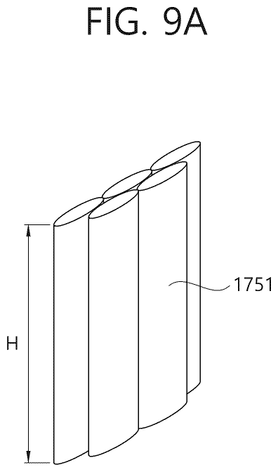

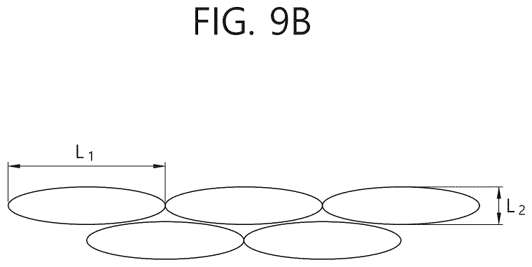

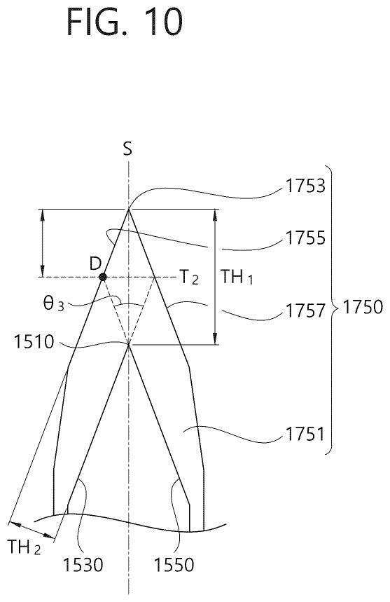

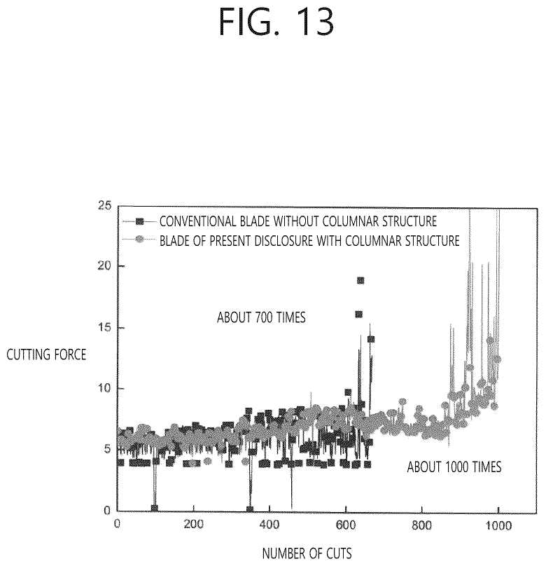

Next, FIG. 5 is an enlarged cross-sectional view of an area A illustrated in FIG. 4, FIG. 6 is a configuration diagram illustrating a substrate and a metal coating layer in the cutting edge area of the blade illustrated in FIG. 5, FIG. 7 is an enlarged cross-sectional view of an area B illustrated in FIG. 6, FIG. 8 is a schematic process diagram of forming a plurality of columnar structures illustrated in FIGS. 5 to 7 by a sputtering process, FIGS. 9A and 9B are schematic configuration diagrams of a shape of a columnar structure of a razor blade according to an embodiment of the present disclosure, FIG. 10 is a first shape view of a substrate and a metal coating layer in a cutting edge area of the blade illustrated in FIG. 6, FIG. 11 is a cross-sectional view illustrating a cutting edge area facing a skin surface, FIGS. 12A to 12C are cross-sectional views illustrating a relative angle between the skin surface and the cutting edge area illustrated in FIG. 11, and FIG. 13 is a graph of a durability test of a conventional blade and a blade of a razor cartridge according to an embodiment of the present disclosure.

As illustrated in FIGS. 5 to 13, the blade 1000 according to the embodiment of the present disclosure includes a base portion 1100, a bent portion 1200, and an edge portion 1300, and the base portion 1100, the bent portion 1200, and the edge portion 1300 constitute a part of the blade 1000, respectively. The blade 1000 includes the base portion 1100, the bent portion 1200, and the edge portion 1300, and may be manufactured integrally, but is not necessarily limited thereto, and may have a shape in which a cutting edge is attached to the blade support.

The blade 1000 includes a substrate 1500 and a coating layer 1700 formed by being laminated on the substrate 1500. A cutting edge 1600 including a substrate tip 1510 and a coating tip 1753, which will be described later, is formed in the tip area, which is a free end of the blade 1000.

The substrate 1500 forms the basic structure of the blade 1000 and is used as a base material for manufacturing the blade 1000. The substrate 1500 includes the substrate tip 1510, a first surface 1530, and a second surface 1550. The substrate tip 1510 is provided to form a final tip 1720 when the coating layer 1700 is formed on the substrate 1500. The substrate 1500 is mainly made of stainless steel, but silicon or ceramic may be used.

Referring to FIG. 5, the first surface 1530 and the second surface 1550 extend in different directions from the substrate tip 1510 at a constant inclination. Specifically, as an example of the present disclosure, the first surface 1530 corresponds to one side surface that contacts the skin surface (F: see FIGS. 11 and 12A and 12B) during shaving, and the second surface 1550 corresponds to the other side surface facing the one side surface.

Referring to FIGS. 5 to 7, the first surface 1530 and the second surface 1550 form the substrate tip 1510, and the coating layer 1700 is formed on the first surface 1530 and the second surface 1550.

Referring to FIG. 5, the cutting edge 1600 is formed in a tip area of the edge portion 1300. The cutting edge 1600 performs a function of substantially cutting body hair during shaving. At least a portion of the cutting edge 1600 is exposed to the top of the blade housing 510 and comes into contact with body hair during shaving.

The coating layer 1700 of the blade 1000 according to the embodiment of the present disclosure includes a final tip 1720, a resin coating layer 1740, and a metal coating layer 1750.

The final tip 1720 forms the tip of the cutting edge 1600. The final tip 1720 is formed by the coating layer 1700 formed on the substrate 1600.

The resin coating layer 1740 is positioned on the metal coating layer 1750 to form the outer surface of the blade 1000. The resin coating layer 1740 may include polytetrafluoroethylene (PTFE) as an example, but is not limited thereto and resins of various materials may be used.

The metal coating layer 1750 is coated between the substrate 1500 and the resin coating layer 1740. The metal coating layer 1750 may include at least one of CrB, CrC, or CrCB based on Cr or include at least one of Ti, TiC, TiB, TiCB, TiAlC, or TiSiC based on Ti, but is not necessarily limited thereto.

More specifically, the metal coating layer 1750 may be composed of a heterogeneous material, and in an embodiment, the heterogeneous material may include a metal material and boron B. In one embodiment, the metal material is described for the case of Cr, but is not necessarily limited thereto, and may be any one of Ni, Ti, W, and Nb in addition to Cr. Furthermore, among heterogeneous materials, B may be replaced with C. As a result, the metal coating layer 1750 may be formed using a composite single target that is a combination of any one of Cr, Ni, Ti, W, and Nb and any one of B and C, or a partial target having form bonded in a crystallographic manner.

The metal coating layer 1750 is formed by a physical vapor deposition (PVD) method. In the physical vapor deposition method, the metal coating layer is formed on the substrate 1500 by any one sputtering process of DC Sputter, DC Magnetron Sputter, DC Unbalanced Magnetron Sputter, and RF Sputter, and is formed in a state where the temperature of the substrate 1500 is formed at 100 degrees or more. Specifically, the metal coating layer 1750 is formed when the temperature of the substrate 1500 is between 150 degrees and 400 degrees.

In the metal coating layer 1750, thicknesses of the coating formed on the first surface 1530, the substrate tip 1510, and the second surface 1550 based on the temperature of the substrate 1500, a pressure difference, and a moving speed of the sputtering target may be different from each other.

Referring to FIG. 8, the metal coating layer 1750 is formed in the order of the second surface 1550, the substrate tip 1510, and the first surface 1550 of the substrate 1500 along the moving direction of the substrate 1500 by a sputtering target 800. A moving section of the substrate 1500 may be divided into a first moving section 810, a second moving section 820, and a third moving section 830 according to the position where the metal coating layer 1750 is formed. Hereinafter, the moving sections will be described together with a first columnar structure 1751a, a second columnar structure 1751b, and a third columnar structure 1751c to be described later in FIGS. 6 and 7.

The first moving section 810 is a section in which the metal coating layer 1750 is formed on the second surface 1550, and the substrate 1500 moves faster in the first moving section 810 than in the second moving section 820. The metal coating layer 1750 formed on the second surface 1550 may have a smaller height than the metal coating layer 1750 formed on the substrate tip 1510, and as a result, the second columnar structure 1751b may have a smaller height than the third columnar structure 1751c.

The second moving section 820 is a section in which the metal coating layer 1750 is formed on the substrate tip 1510, and the substrate 1500 may move more slowly in the second moving section 820 than in the first moving section 810 and the third moving section 830. As a result, the metal coating layer 1750 formed on the substrate tip 1510 may have a higher height than the metal coating layer 1750 formed on the first surface 1530 and the second surface 1550, and as a result, the third columnar structure 1751c may have a higher height than the first columnar structure 1751a and the second columnar structure 1751b.

The third moving section 830 is a section in which the metal coating layer 1750 is formed on the first surface 1530, and the substrate 1500 moves faster in the third moving section 830 than in the second moving section 820. The metal coating layer 1750 formed on the first surface 1550 may have a smaller height than the metal coating layer 1750 formed on the substrate tip 1510, and as a result, the first columnar structure 1751a may have a smaller height than the third columnar structure 1751c.

Here, the moving speed of the substrate 1500 of the first moving section 810 and the third moving section 830 may be a speed at which the metal coating layer 1750 can be deposited at 0.5 nanometers or more per second, and the second moving section 820 may be stacked at a speed of less than 0.5 nanometers per second. More specifically, a ratio of the moving speed of the substrate 1500 in the first moving section 810 and the third moving section 830 to the moving speed of the substrate 1500 in the second moving section 820 may have a value of about 1:0.7.

In addition, as the substrate 1500 moves slowly in the second moving section 820 compared to the first moving section 810 and the second moving section 830, the third columnar structure 1751c may have a radial shape around the substrate tip 1510 with the substrate tip 1510 as the center.

The metal coating layer 1750 is formed on the substrate tip 1510, the first surface 1530, and the second surface 1550, and includes a plurality of columnar structures 1751 formed in a direction toward the outside of the substrate 1500. In addition, the metal coating layer 1750 further includes a coating tip 1753 formed on the substrate tip 1510, a first coating surface 1755 extending from the coating tip 1753 to one side, and a second coating surface 1757 extending from the coating tip 1753 to the other side.

Referring to FIG. 6, as an embodiment of the present disclosure, when a metal coating layer 1750 is formed by sputtering, the plurality of columnar structures 1751 are formed extending outward from the surface of the substrate 1500 in the same direction as a lamination direction of the metal coating layer 1750 on the substrate 1500 by the Self Glancing Angle Deposition (SGAD) technique. The plurality of columnar structures 1751 are formed to have angles θ1 and θ2 of 5 degrees to 90 degrees with respect to the first surface 1530 and the second surface 1550. The plurality of columnar structures 1751 include a plurality of first columnar structures 1751a formed in an outward direction from an upper portion of the first surface 1530 and a plurality of second columnar structures 1751b formed in an outward direction from an upper portion of the second surface 1550. In addition, the plurality of columnar structures 1751 further include a plurality of third columnar structures 1751c formed on the substrate tip 1510.

Referring to FIG. 6, the plurality of first columnar structures 1751a are formed on the first surface 1530. As the plurality of first columnar structures 1751a are closer to the substrate tip 1510, the angle θ1 with respect to the first surface 1530 decreases. That is, when the plurality of first columnar structures 1751a are formed on the first surface 1530, the angle θ1 with respect to the first surface 1530 gradually decreases in the direction of the substrate tip 1510.

The plurality of first columnar structures 1751a are not formed in a straight line when substantially formed on the first surface 1530, but have a shape that curves toward the coating tip 1753 as they move away from the first surface 1530. That is, the plurality of first columnar structures 1751a have a shape in which curvature increases compared to a shape closer to the first surface 1530 as the distance from the first surface 1530 increases.

The plurality of second columnar structures 1751b are formed on the second surface 1550. As the plurality of second columnar structures 1751b are closer to the substrate tip 1510, the angle θ2 with respect to the second surface 1550 decreases. That is, when the plurality of second columnar structures 1751b are formed above the second surface 1550, the angle θ2 with respect to the second surface gradually decreases in the direction of the substrate tip 1510.

The plurality of second columnar structures 1751b are not formed in a straight line when formed on the second surface 1550 like the plurality of first columnar structures 1751a described above, but have a shape bent toward the coating tip 1753 as the distance from the second surface 1550 increases. In detail, the plurality of second columnar structures 1751b have a shape in which the curvature increases compared to a shape closer to the second surface 1550 as the distance from the second surface 1550 increases.

The plurality of third columnar structures 1751c are formed on the substrate tip 1510. The plurality of third columnar structures 1751c are radially formed around the substrate tip 1510. Substantially, the plurality of third columnar structures 1751c are formed in the coating tip 1753 area.

The distance between the substrate tip 1510 and the coating tip 1753 has a value between 20 nanometers and 550 nanometers. Meanwhile, the plurality of columnar structures 1751 are formed over about 300 nanometers in a direction from the substrate tip toward the coating tip 1753.

As illustrated in FIGS. 9A and 9B, at least one of a height H of the plurality of first columnar structures 1751a or a height H of the plurality of second columnar structures 1751b may be about 100 nanometers or less. Meanwhile, the height H of the plurality of third columnar structures 1751c may be greater than about 100 nanometers.

Referring to FIGS. 7 and 9A and 9B, the columnar structure 175) of an elliptical column is structurally strong against external forces applied in the height direction, and since the blade 1000 having the radial columnar structure 1751 centered on the substrate tip 1510 may have a columnar structure extending in a horizontal direction for various pressing directions during shaving, durability of the blade 1000 may be increased.

The plurality of columnar structures 1751 may be approximated as an elliptical column shape. As an embodiment of the present disclosure, the plurality of columnar structures 1751 are formed in an elliptical shape having a long axis L1 of about 25 nanometers and a short axis L2 of about 3 nanometers, but are not limited thereto, and the columnar structure 1751 may be formed by changing the numerical values of the long axis L1 and the short axis L2.

Referring to FIG. 10, a ratio of the second thickness TH2 of the metal coating layer 1750 formed on the first surface 1530 and the second surface 1550 to a first thickness TH1 of the metal coating layer 1750 between the substrate tip 1510 and the coating tip 1753 is 1:1 to 1:0.3. That is, when examining that the ratio of the second thickness TH2 to the first thickness TH1 is 1:1 to 1:0.3, the first thickness TH1 is relatively equal to or greater than the second thickness TH2.

Referring to FIG. 10, an angle θ3 between an extension direction of the columnar structure 1751 located at a point D where a virtual line T2 passing through a point about 100 nanometers away from the coating tip 1753 intersects any one of the first coating surface 1755 and the second coating surface 1757 and an extension direction of the first surface has a range of 50 degrees to 80 degrees.

Meanwhile, referring to FIG. 11, an angle θ4 between the extension direction of the columnar structure 1751 located at a point D where a virtual line T3 passing through a point about 100 nanometers away from the coating tip 1753 intersects any one of the first coating surface 1755 and the second coating surface 1757 and the first surface has a range of 35 degrees to 110 degrees.

Referring to FIGS. 12A and 12B, the blade 1000 has the plurality of columnar structures 1751 formed radially from the substrate tip 1510, and thus, the blade 1000 may include various columnar structures 1751 corresponding to external forces generated during shaving according to an angle BA of the blade 100. Here, the external force generally means a force acting in a direction perpendicular to the hair.

For example, referring to FIG. 12A, when the angle BA of the blade 1000 is about 5 degrees or less, the columnar structure 1751 illustrated by a solid line between the substrate tip 1510 and the coating tip 1753 among the plurality of columnar structures 1741 supports the external force acting in the horizontal direction with the skin surface F, and thus, can improve durability.

Referring to FIG. 12B, when the angle BA of the blade 1000 is about 10 degrees, the columnar structure 1751 illustrated by a solid between the substrate tip 1510 and the coating tip 1753 and the second surface 1550 and in the direction of the second surface 1550 among the plurality of columnar structures 1751 supports the external force acting in the horizontal direction with the skin surface F, and thus, it is possible to improve the durability.

Moreover, referring to FIG. 12C, when the angle BA of the blade 1000 is about 22 degrees, the columnar structure 1751 in the direction of the second surface 1550 illustrated by a solid line supports the external force acting in the horizontal direction with the skin surface F, and it is possible to improve the durability.

Referring to FIG. 13, in a graph of the durability test of the blade 1000 of the razor cartridge 500 according to the embodiment of the present disclosure and the conventional blade, it can be confirmed that durability is improved by forming the plurality of columnar structures 1751.

As illustrated in the graph of FIG. 13, the conventional blade without the plurality of columnar structures 1751 and the blade 1000 with the plurality of columnar structures 1751 of the embodiment of the present disclosure have similar cutting forces in the shaving test of about 700 times. However, in the conventional blade without the plurality of columnar structures 1751, the cutting force increases, that is, durability is reduced after about 700 shaving tests.

Meanwhile, in the blade 1000 having the plurality of columnar structures 1751 of the embodiment of the present disclosure, the cutting force exists even when going through a shaving test of about 1000 or more times beyond 700 times of shaving. Accordingly, it can be seen that the blade 1000 having the plurality of columnar structures 1751 according to the embodiment of the present disclosure has relatively strong durability compared to the conventional blade without the plurality of columnar structures 1751.

Although embodiments of the present disclosure have been described with reference to the accompanying drawings, a person with ordinary knowledge in the technical field to which the present disclosure belongs will be able to understand that the present disclosure may be implemented in other specific forms without changing the technical spirit or essential features. Therefore, the embodiments described above should be understood as illustrative in all respects and not limiting. The scope of the present disclosure is indicated by claims to be described later rather than the detailed description above, and all changes or modified forms derived from the meaning and scope of the claims and their equivalent concepts should be construed as being included in the scope of the present disclosure.

What is claimed is:

1. A razor blade comprising:
a substrate including a substrate tip, a first surface extending from the substrate tip to a first side, and a second surface extending from the substrate tip to a second side opposing the first side; and
a metal coating layer formed on the first surface, the second surface, and the substrate tip,
wherein the metal coating layer includes a plurality of columnar structures formed toward an outside of the substrate.

2. The razor blade of claim 1, wherein the plurality of columnar structures include a first columnar structure formed on the first surface such that an angle with respect to the first surface becomes smaller as the first columnar structure is closer to the substrate tip.

3. The razor blade of claim 1, wherein the plurality of columnar structures include a plurality of first columnar structures formed on the first surface, and
wherein the plurality of first columnar structures have an angle with respect to the first surface that decreases as a distance from the first surface increases.

4. The razor blade of claim 1, wherein the plurality of columnar structures include a second columnar structure formed on the second surface such that an angle with respect to the second surface becomes smaller as the second columnar structure is closer to the substrate tip.

5. The razor blade of claim 1, wherein the plurality of columnar structures include a plurality of second columnar structures formed on the upper portion of the second surface, and
wherein the plurality of second columnar structures have an angle with respect to the second surface that decreases as the distance from the second surface increases.

6. The razor blade of claim 1, wherein the plurality of columnar structures include a plurality of third columnar structures formed on the substrate tip and radially formed around the substrate tip.

7. The razor blade of claim 1, wherein the metal coating layer includes a coating tip formed on the substrate tip, and
wherein the plurality of columnar structures are formed within 300 nanometers from the coating tip.

8. The razor blade of claim 1, wherein the metal coating layer includes a coating tip formed on the substrate tip, and
wherein a distance between the substrate tip and the coating tip includes a value between 20 nanometers and 550 nanometers.

9. The razor blade of claim 1, wherein the plurality of columnar structures include a plurality of first columnar structures formed on the first surface and a plurality of second columnar structures formed on the second surface, and
wherein the plurality of first columnar structures and the plurality of second columnar structures have a height of 100 nanometers or less.

10. The razor blade of claim 1, wherein the plurality of columnar structures include a plurality of first columnar structures formed on the first surface, a plurality of second columnar structures formed on the second surface, and a plurality of third columnar structures formed on the substrate tip, and
wherein at least one of the plurality of first columnar structures or the second columnar structures have a height of 100 nanometers or less, and at least one of the plurality of third columnar structures has a height of more than 100 nanometers.

11. The razor blade of claim 1, wherein the metal coating layer includes a coating tip formed on the substrate tip, and
wherein a ratio of a thickness of the metal coating layer formed on the first surface and the second surface to a thickness of the metal coating layer between the substrate tip and the coating tip ranges from 1:1 to 1:0.3.

12. The razor blade of claim 1, wherein the plurality of columnar structures are formed at an angle of 5 degrees to 90 degrees with respect to the first surface and the second surface.

13. The razor blade of claim 1, wherein the plurality of columnar structures include a plurality of first columnar structures formed on the first surface,
wherein the metal coating layer includes a coating tip formed on the substrate tip, a first coating surface extending from the coating tip to one side, and a second coating surface extending from the coating tip to the other side, and
wherein an angle between an extension direction of the plurality of columnar structures located at the point where a virtual line passing through a point about 100 nanometers away from the coating tip intersects any one of the first coating surface or the second coating surface, and an extension direction of the first surface is 50 degrees to 80 degrees.

14. The razor blade of claim 1, wherein the metal coating layer includes at least one of CrB, CrC, or CrCB based on Cr.

15. The razor blade of claim 1, wherein the metal coating layer includes any one of TiC, TiB, TiCB, TiAlC, or TiSiC based on Ti.

16. A razor cartridge comprising:
at least one blade including an edge portion and a cutting edge formed at a tip of the edge portion; and
a blade housing configured to accommodate the blade in a longitudinal direction such that at least a portion of the cutting edge is exposed upward,
wherein the razor blade includes:
a substrate including a substrate tip, a first surface extending from the substrate tip to a first side, and a second surface extending from the substrate tip to a second side opposing the first side, and
a metal coating layer formed on the first surface, the second surface, and the substrate tip, and
wherein the metal coating layer includes a plurality of columnar structures formed toward an outside of the substrate.

17. The razor cartridge of claim 16, wherein the plurality of columnar structures include a plurality of first columnar structures formed on the first surface and configured to face a skin surface during shaving,
wherein the metal coating layer includes a coating tip formed on the substrate tip, a first coating surface extending from the coating tip to a third side, and a second coating surface extending from the coating tip to a fourth side opposing the third side, and
wherein an angle between an extension direction of the plurality of columnar structures located at a point where a virtual line passing through a point about 100 nanometers away from the coating tip intersects any one of the first coating surface or the second coating surface, and the skin surface is 35 degrees to 110 degrees.
